(19) United States
(12) Patent Application Publication
(10) Pub. No.: US 2023/0302847 A1
(43) Pub. Date: Sep. 28, 2023

(54) ASSEMBLY AND METHOD FOR GROWING CRYSTALLINE ORNAMENT, AND SAME

(71) Applicant: Shenzhen BLACK TECH Co., Ltd., Shenzhen (CN)

(72) Inventor: Lianwu Huang, Shenzhen (CN)

(21) Appl. No.: 18/325,943

(22) Filed: May 30, 2023

(51) Int. Cl. B44F 9/08

(52) U.S. Cl. CPC B44F 9/08

(57) ABSTRACT

The present disclosure discloses an assembly and a method for growing a crystalline ornament and the crystalline ornament. The assembly for growing a crystalline ornament, including: a base material; a growth fluid supplier, which is provided with a storage space and an opening communicating with the storage space, and the storage space is used for storing a growth fluid; a connector; and a support member, which is detachably connected to the base material through the connector and erected on the opening, and the base material is placed in the storage space.

### TECHNICAL FIELD

The present disclosure relates to the field of crystal decoration, in particular to an assembly and a method for growing a crystalline ornament and the crystalline ornament.

### BACKGROUND

A variety of crystal ornaments for indoor or outdoor decoration exist in real life, specifically can absorb a growth fluid and grow into crystalline ornaments, and however the crystalline ornaments that need to absorb the growth fluid to grow into the growth crystal may exist the problem of not high structural stability.

### SUMMARY

In the first aspect, the present disclosure discloses an assembly for growing a crystalline ornament, including:
a base material;
a growth fluid supplier, which is provided with a storage space and an opening communicating with the storage space, and the storage space is used for storing a growth fluid;
a connector; and
a support member, which is detachably connected to the base material through the connector and erected on the opening, and the base material is placed in the storage space.

Further, the base material is made of a water absorbing material.

Further, the base material is spherical.

Further, a plurality of water absorbing holes are distributed on an outer surface of the base material, and the water absorbing holes are conducted mutually.

Further, a support hole is formed in the support member, the connector includes a connecting rod and a tail cap, the connecting rod includes a first end and a second end, the base material is fixedly connected to the first end of the connecting rod, and when the second end of the connecting rod penetrates into a second side of the support member from a first side of the support member through the support hole, the tail cap is detachably covered on the second end of the connecting rod, so that the second end of the connecting rod is stopped at the second side.

Further, a second end of the connecting rod is provided with a connecting end, one end of a tail cap is provided with a connecting hole, and the connecting end is contained in the connecting hole and connected to a hole wall of the connecting hole.

Further, when a base material is placed in a storage space, the water absorbing holes of the base material are capable of absorbing a growth fluid in the storage space, so as to form a crystalline ornament.

In the second aspect, the present disclosure also discloses a method for growing a crystalline ornament, including the following steps of: providing a base material, a connector, a support member, a growth fluid supplier, a supply powder and a solvent, wherein the growth fluid supplier is provided with a storage space and an opening communicating with the storage space, and the connector includes a first end and a second end; and the first end of the connector is connected to the base material, and the second end of the connector is detachably connected to the support member; pouring the supply powder and the solvent into the storage space, and stirring and mixing the supply powder and the solvent, so as to obtain a growth fluid; erecting the support member on the opening, and soaking the base material into the growth fluid; and the base material absorbing the growth fluid, so as to form a crystalline ornament on a surface on the base material.

Further, the step that the first end of the connector is connected to the base material and the second end of the collector is connected to the support member is as follows: a support hole is formed in the support member, the connector includes a connecting rod and a tail cap, the connecting rod includes the first end and the second end, the base material is fixedly connected to the first end of the connecting rod, and when the second end of the connecting rod penetrates into a second side of the support member from a first side of the support member through the support hole, the tail cap is detachably covered on the second end of the connecting rod, so that the second end of the connecting rod is stopped at the second side.

Further, the step after the base material absorbs the growth fluid, so as to form a crystalline ornament on a surface on the base material is as follows: disconnecting the second end of the connector with the support member; providing a base; and detachably inserting the second end of the connector to the base, so as to obtain a growable crystal.

Further, the step of base material absorbing the growth fluid, so as to form a crystalline ornament on a surface on the base material is as follows:
forming a plurality of water absorbing holes communicating with each other in the surface of the base material, the water absorbing holes absorbing the growth fluid so as to form an irregular crystalline ornament on the surface of the base material.

Further, the base is provided with a fixing matrix, which is fixedly connected inside the base, and the second end of the connector is detachably inserted into the fixing matrix.

In the third aspect, the present disclosure discloses a crystalline ornament, including: a base material, wherein a crystalline ornament is provided on an outer surface of the base material; a base, and a connector, wherein the connector includes a first end and a second end, the first end of the connector is connected to the base material, and the second end of the connector is connected to the base.

Further, the first end of the connector is connected to the base material, and the second end of the connector is detachably connected to the base.

Further, a base is provided with a fixing matrix, which is fixed connected inside the base, and the second end of the connector is detachably inserted into the fixing matrix.

Further, a placing hole is formed in the fixing matrix, and the second end of the connector is detachably inserted into the placing hole.

Further, an outer contour of the fixing matrix fits with an inner contour of a base, so that the fixing matrix is tightly fixed in a storage space of the base, and the placing hole is formed in a central position of the fixing matrix; and a top end of the fixing matrix is lower than that of the base and has a predetermined distance from the top end of the base.

Further, the base material is made of a water absorbing material, the base is a plastic material, and a fixing matrix includes a foam material.

Further, the base material is spherical, a plurality of water absorbing holes are distributed in an outer surface of the base material, and the water absorbing holes are conducted mutually.

Further, the crystalline ornament is an irregular crystalline ornament.

### BRIEF DESCRIPTION OF THE DRAWINGS

In order to explain the technical solutions of the embodiments of the present disclosure more clearly, the following will briefly introduce the accompanying drawings used in the embodiments. Apparently, the drawings in the following description are only some embodiments of the present disclosure. Those of ordinary skill in the art can obtain other drawings based on these drawings without creative work.

FIG. 1 is an exploded diagram of one embodiment of an assembly for growing a crystalline ornament in the present disclosure;

FIG. 2 is a look-down structural diagram of one embodiment of an assembly for growing a crystalline ornament in the present disclosure;

FIG. 3 is a schematic diagram of a growth fluid supplier of one embodiment of an assembly for growing a crystalline ornament in the present disclosure;

FIG. 4 is a base structural diagram of one embodiment of an assembly for growing a crystalline ornament in the present disclosure;

FIG. 5 is a support hole schematic diagram of one embodiment of an assembly for growing a crystalline ornament in the present disclosure;

FIG. 6 is a schematic diagram for splitting a connector of one embodiment of an assembly for growing a crystalline ornament in the present disclosure;

FIG. 7 is a structural schematic diagram of a tail cap of one embodiment of an assembly for growing a crystalline ornament in the present disclosure;

FIG. 8 is a base material schematic diagram of one embodiment of an assembly for growing a crystalline ornament in the present disclosure;

FIG. 9 is a schematic diagram of a crystal decoration body of one embodiment of a crystalline ornament for growing a crystalline ornament in the present disclosure;

FIG. 10 is a flowchart of one embodiment of a method for growing a crystalline ornament in the present disclosure.

### DETAILED DESCRIPTION OF THE EMBODIMENTS

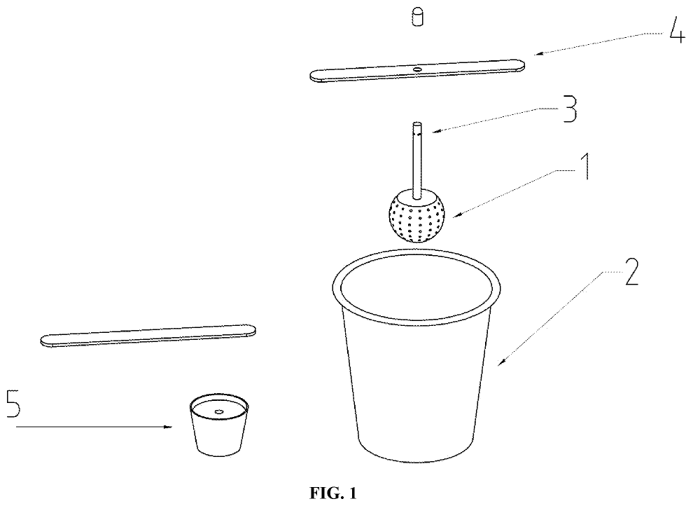

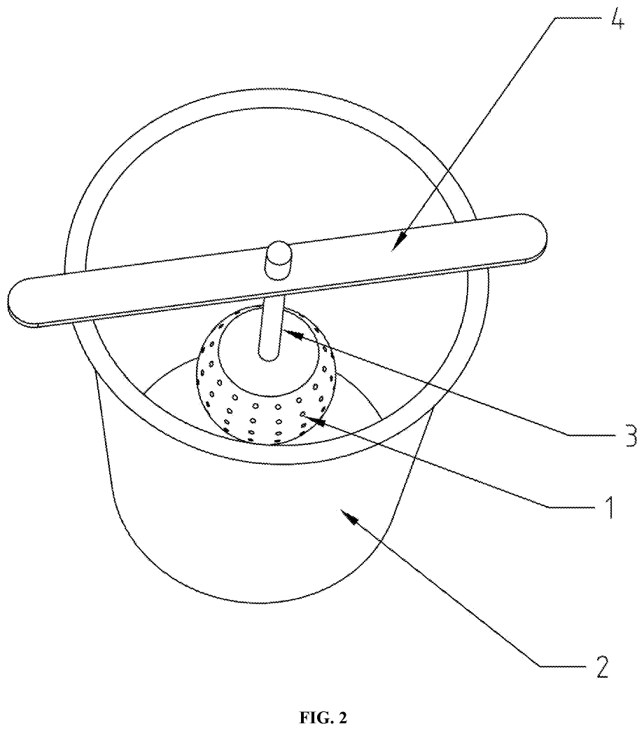

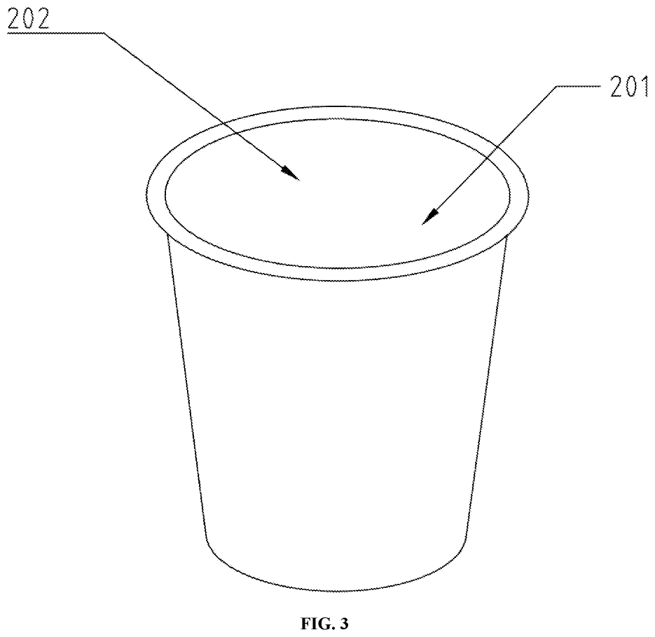

Referring to FIGS. 1 to 3, which is an assembly for growing a crystalline ornament provided by one embodiment of the present disclosure, including a base material 1, a growth fluid supplier 2, a connector 3 and a support member 4, where the growth fluid supplier 2 is provided with a storage space 201 and an opening 202 communicating with the storage space 201, the storage space 201 is used for containing the growth fluid, the support member 4 is detachably connected to the base material 1 through the connector 3, the support member 4 is erected on the opening 202, and the base material 1 is placed in the storage space 201;

In this embodiment, the base material 1 is used for absorbing the growth fluid in the growth fluid supplier 2, so that the base material 1 grows into growth crystal after absorbing the growth fluid fully; the growth fluid supplier 2 is used for storing the growth fluid, through which the base material 1 grows; the connector 3 is used for connecting the base material 1 with the support member 4, so as to stabilize the base material 1 on the support member 4; the support member 4 is used for stabilizing the base material 1 in the growth fluid supplier 2; and the growth fluid supplier 2 further includes a supply powder and a solvent, which are used for preparing the growth fluid.

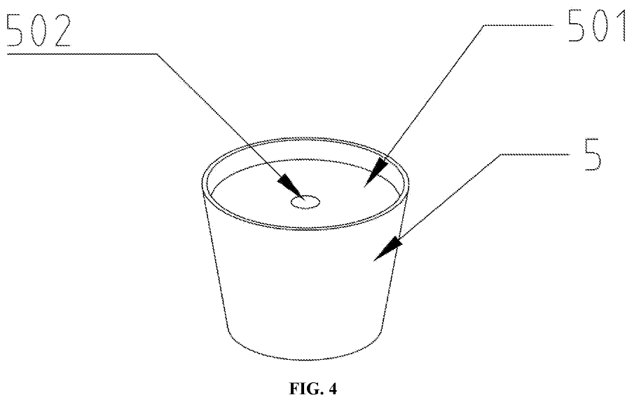

Referring to FIG. 4, the assembly for growing the crystalline ornament further includes a base 5, where the base 5 is used for placing the connector 3, one end of the connector 3 is connected to the base material 1 while the other end of the connector 3 is detachably connected to the base 5, the base 5 is provided with a fixing matrix 501 which is fixedly connected in the base 5, the connector 3 is inserted into the fixing matrix 501, a placing hole 502 is formed in an upper surface of the fixing matrix 501, the placing hole 502 is conducted with an interior of the base 5, and the placing hole 502 is used for stabilizing the formed base material 1 in the base 5;

In this embodiment, the base 5 is used for placing the growth crystal that completes the absorption of the growth fluid, the fixing matrix 501 is used for fixing the connector 3 in the base 5, and the placing hole 502 is used for stabilizing the growth crystal in the base 5;

Specifically, when a user obtains the growth crystal that grows after absorbing the growth fluid fully, a tail cap 302 at a tail of the connector 3 may be taken off, the connector 3 is disassembled from the support member 4, the tail of the connector 3 is inserted into the placing hole 502 that is formed in the fixing matrix 501 of the base 5, the growth crystal is fixed in the base 5, so the complete growth crystal may be obtained.

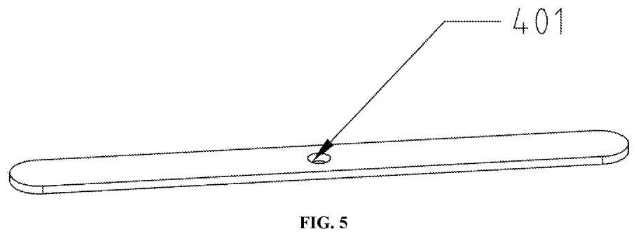

Referring to FIG. 5, a support hole 401 is formed in the support member 4, and the connector 3 penetrates through the support hole 401 and is in tight contact with a hole wall of the support hole 401;

In this embodiment, the support hole 401 is used for fixing the connector 3 on the support member 4, so as to avoid the connector 3 sliding off the support member 4;

Specifically, when the user needs to assemble the material of the growable crystal, first a head of the connector 3 is inserted into the base material 1, and the tail cap 302 arranged at the tail of the connector 3 is taken off; and the connector 3 is inserted into the support hole 401 on the support member 4 along the tail of the connector 3 and passes through the support hole 401, and the connector 3 can be stabilized in the support member 4.

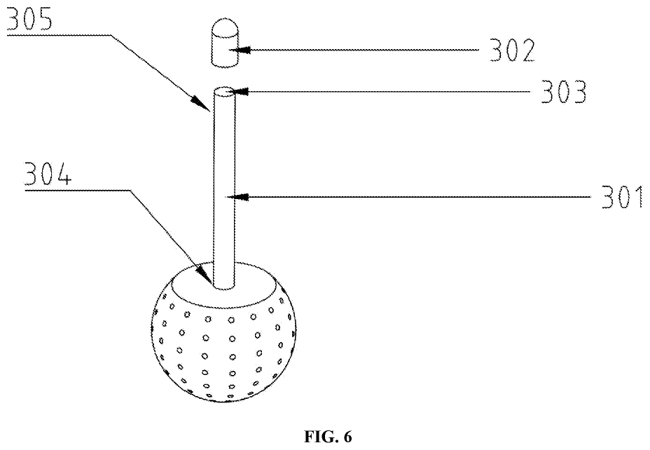

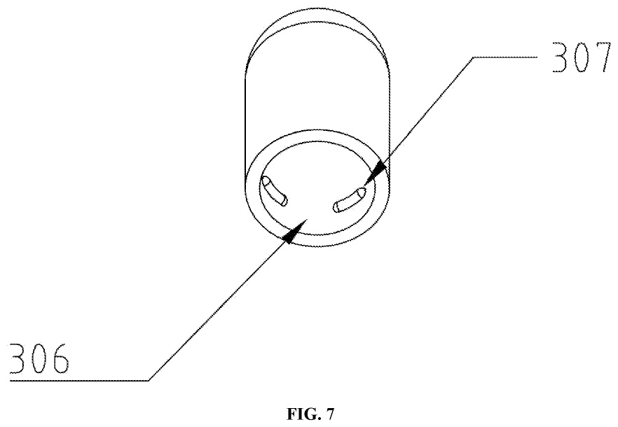

Referring to FIGS. 6-7, the connector 3 includes a connecting rod 301 and a tail cap 302, the connecting rod 301 includes a first end 304 and a second end 305, the base material 1 is fixedly connected to the first end 304 of the connecting rod 301, and when the second end 305 of the connecting rod 301 penetrates into a second side of the support member 4 from a first side of the support member 4 through the support hole 401, the tail cap 302 is detachably covered on the second end 305 of the connecting rod 301, so that the second end 305 of the connecting rod 301 is stopped at the second side; the second end 305 of the connecting rod 301 is provided with a connecting end 303, a connecting hole 306 is formed in one end of the tail cap 302, and the connecting end 303 is contained in the connecting hole 306 and connected to a hole wall 307 of the connecting hole 306.

In this embodiment, the first end 304 of the connecting rod 301 is used for connecting the base material 1, the second end 305 of the connecting rod 301 is used for penetrating through and connecting to the support member 4, and the tail cap 302 is used for stabilizing the connecting rod 301 on the support member 4, so as to avoid the connector 3 sliding off the support member 4;

Specifically, when the user needs to assemble the material of the growable crystal, first the first end 304 of the connecting rod 301 is introduced into the base material 1, and then the second end 305 of the connecting rod 301 penetrates through the support hole 401 on the support member 4 and resists to the second side of the support member 4; after the detachable tail cap 302 is covered to the second end 305 of the connecting rod 301, the connecting rod 301 is fixed in the support member 4; and meanwhile the connecting end 303, arranged at the second end 305 of the connecting rod 301, can form a nesting connection with the connecting hole that is at one end of the tail cap 302, and the second end 305 of the connecting rod 301 penetrates into the support hole 401, so as to strengthen the stable degree of the connecting rod 301 in the support member 4.

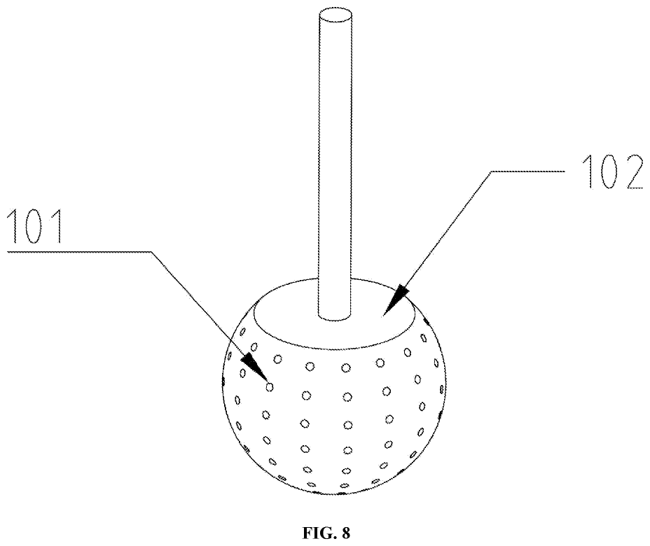

Referring to FIG. 8, which is a growable crystal in one embodiment of the present disclosure, a bottom end of the base material 1 is a circular cross section 102, a plurality of water absorbing holes 101 are distributed in an outer surface of the base material 1, the water absorbing holes 101 are conducted mutually, and the base material 1 is made of a water absorbing material.

In this embodiment, the cross section 102 is used for connecting one end of the connector 3 to the base material 1 conveniently and smoothly, and the base material 1 can uniformly absorb the growth fluid of the growth fluid supplier 2 from various angles through the water absorbing holes 101, so as to grow into the growth crystal;

Specifically, when the user needs to perform growth fluid soaking on the base material 1, the head of the connector 3 needs to be inserted into the base material 1 through the cross section 102 of the base material 1, and then the base material 1 stretches into the growth fluid of the growth fluid supplier 2 by operating the tail of the connector 3, so that the growth fluid uniformly flows into various water absorbing holes 101 in the surface of the base material 1, that is, the growth fluid soaking process of the base material 1 may be completed.

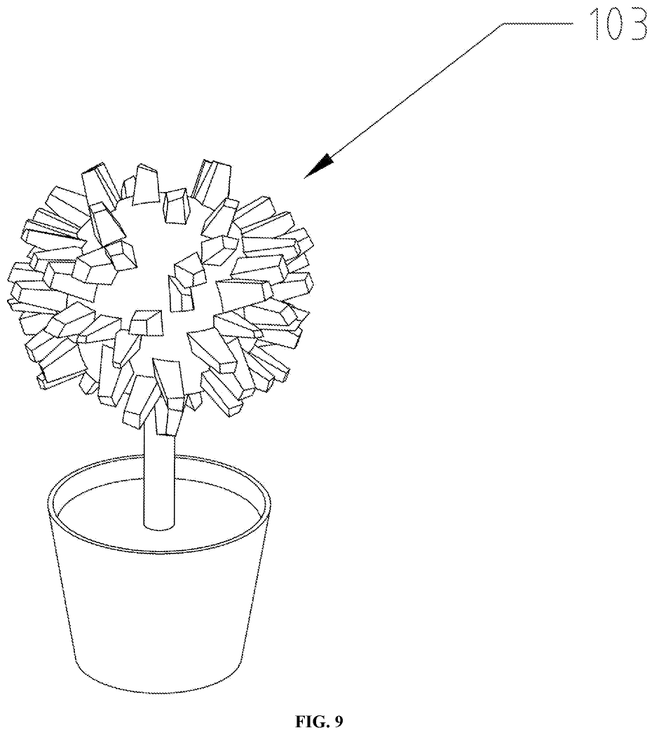

Referring to FIG. 9, the present disclosure further provides a crystalline ornament 103 achieved by applying the above method, including a base material 1, a crystalline ornament 103 arranged on an outer surface of the base material 1, a base 5 and a connector 3. The connector 3 includes a first end 304 and a second end 305, the first end 304 of the connector 3 is connected to the base material 1, and the second end 305 of the connector 3 is connected to the base 5.

In this embodiment, since the crystallization and growth and the preparation process for the growth fluid supplier 2 have been stated in the above method, and elaboration will not be made herein. Specifically, when a user obtains the growth crystal that grows after absorbing the growth fluid fully, a tail cap 302 at a tail of the connector 3 may be taken off, the connector 3 is disassembled from the support member 4, the tail of the connector 3 is inserted into the placing hole 502 that is formed in the fixing matrix 501 of the base 5, the growth crystal is fixed in the base 5, so as to obtain the crystalline ornament 103.

It is to be noted that an outer contour of the fixing matrix 501 fits with an inner contour of the base 5, so that the fixing matrix 501 is tightly fixed in the storage space of the base 5, and the placing hole 502 is located at the central position of the fixing matrix 501 so as to achieve the better support and balance effects; the top end of the fixing matrix 501 is lower than that of the base 5 and has a predetermined distance from the top end of the base 5 so as to achieve the effect of adjusting the center of gravity of the growable crystal well, so that the growable crystal product may be stably placed on a desk or other external objects; and the base 5 may be made of a plastic, and the material of the fixing matrix 501 may include a foam material.

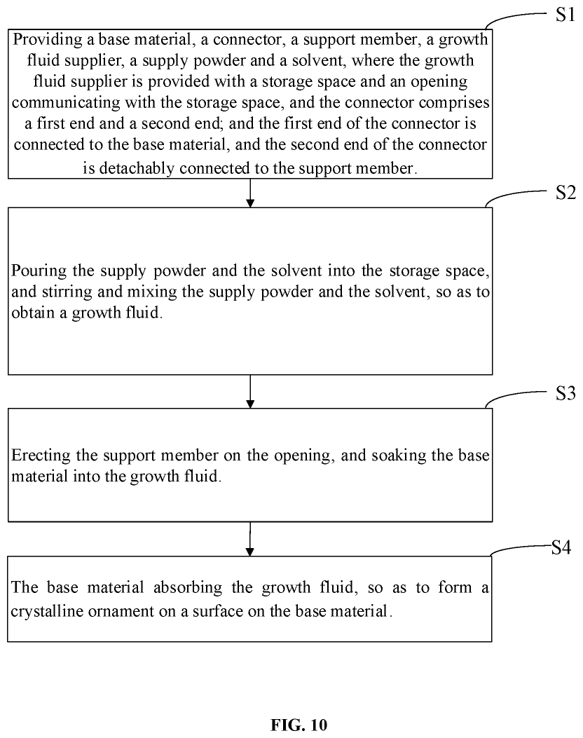

Referring to FIGS. 1 to 10, the present disclosure provides a method for growing a crystalline ornament by using an assembly for growing the crystalline ornament, including the following steps S1-S4.

S1: providing a base material, a connector, a support member, a growth fluid supplier, a supply powder and a solvent, where the growth fluid supplier is provided with a storage space and an opening communicating with the storage space, and the connector includes a first end and a second end; and the first end of the connector is connected to the base material, and the second end of the connector is detachably connected to the support member.

S2: pouring the supply powder and the solvent into the storage space, and stirring and mixing the supply powder and the solvent, so as to obtain a growth fluid.

S3: erecting the support member on the opening, and soaking the base material into the growth fluid.

S4: the base material absorbing the growth fluid, so as to form a crystalline ornament on a surface on the base material.

Specifically, S1 may specifically include: when a user obtains the above crystalline growth material and does not assemble the crystalline growth material, the user needs to prepare the crystalline growth material. First, the first end of the connector stretches into the base material 1; and the base material 1 is movably connected to the first end of the connector 3, then the tail cap at the second end of the connector 3 is disassembled, and the second end of the connector 3 is inserted and penetrates through the support hole on the support member 4; and finally, the tail cap is reassembled on the second end of the connector 3, the connector 3 is fixed in the support member 4, and at this time, the supply fluid and the solvent are not provided in the growth fluid supplier. After the crystalline growth material is assembled successfully, the supply powder and the solvent that have the corresponding weight are prepared to the growth fluid supplier 2, the crystalline material is fixed in the structural assembly, so as to avoid affecting the soaking of the crystalline material due to other unstable factors, such as shaking, vibration and the like when the crystalline material is soaked in the growth fluid supplier, thereby improving the soundness of the crystalline material.

It is to be noted that the material of the base material 1 is the water absorbing material, the material of the connector 3 is specifically the plastic material, the material of the support member 4 is specifically the birch material, the material of the growth fluid supplier 2 is the glass material, the scale of the fluid can be seen from the outside, and the weight ratio of the supply powder to the solvent is 1:10.

S2 may specifically include: when the user completes the assembly for the crystalline growth material, 10 g of supply powder matches with 100 g of solvent to be poured into the growth fluid supplier 2; and after obtaining a mixing solution, the mixing solution of the growth fluid supplier 2 is controlled to a preset scale line, the mixing solution is stirred by a stirring roller, after stirring until the mixing solution is uniformly mixed, waiting for 10-15 min, that is, the growth fluid can be obtained.

S3 may specifically include: when the user prepares the crystalline growth material and the growth fluid, first the base material 1 at the first end of the connector 3 stretches into the growth fluid supplier downwards, so that the base material absorbs the growth fluid in the growth fluid supplier fully, the base material 1 is ensured to be soaked in the growth fluid completely and any operation is not made to the base material during this period, so as to avoid natural or unnatural factors affecting the base material 1 during the soaking period, causing that the base material 1 absorbs the growth fluid unevenly.

S4 may specifically include: after the base material 1 is soaked in the growth fluid supplier 2 for 24 h, the base material has fully absorbed the growth fluid at this time; and after the growth fluid mixed on the surface of the base material 1 is uniformly diluted and wiped through wiping paper, the tail cap at the second end of the connector 3 is taken off, the connector 3 is disassembled from the support member 4, that is, the crystalline ornament growing after the base material 1 absorbs the growth fluid fully can be obtained.

In conclusion, in the present disclosure, the base material 1 is soaked into the supply fluid by arranging the support member 4 for soaking the base material 1 into the supply fluid, so that the base material 1 has a stable structure, which can assist the base material to absorb the growth fluid fixedly in the growth fluid supplier 2, so that the beautiful crystalline ornament with the stable structure may be obtained.

One or more implementation modes are provided above in combination with specific contents, and it is not deemed that the specific implementation of the present disclosure is limited to these specifications. Any technical deductions or replacements approximate or similar to the method and structure of the present disclosure or made under the concept of the present disclosure shall fall within the scope of protection of the present disclosure.

What is claimed is:

1. An assembly for growing a crystalline ornament, comprising:
a base material;
a growth fluid supplier, which is provided with a storage space and an opening communicating with the storage space, and the storage space is used for storing a growth fluid;
a connector; and
a support member, which is detachably connected to the base material through the connector and erected on the opening, and the base material is placed in the storage space.

2. The assembly for growing the crystalline ornament according to claim 1, wherein the base material is made of a water absorbing material.

3. The assembly for growing the crystalline ornament according to claim 1, wherein the base material is spherical.

4. The assembly for growing the crystalline ornament according to claim 1, wherein a plurality of water absorbing holes are distributed on an outer surface of the base material, and the water absorbing holes are conducted mutually.

5. The assembly for growing the crystalline ornament according to claim 1, wherein a support hole is formed in the support member, the connector comprises a connecting rod and a tail cap, the connecting rod comprises a first end and a second end, the base material is fixedly connected to the first end of the connecting rod, and when the second end of the connecting rod penetrates into a second side of the support member from a first side of the support member through the support hole, the tail cap is detachably covered on the second end of the connecting rod, so that the second end of the connecting rod is stopped at the second side.

6. The assembly for growing the crystalline ornament according to claim 1, wherein a second end of the connecting rod is provided with a connecting end, one end of a tail cap is provided with a connecting hole, and the connecting end is contained in the connecting hole and connected to a hole wall of the connecting hole.

7. The assembly for growing the crystalline ornament according to claim 4, wherein when a base material is placed in a storage space, the water absorbing holes of the base material are capable of absorbing a growth fluid in the storage space, so as to form a crystalline ornament.

8. A method for growing a crystalline ornament, comprising the following steps of:
providing a base material, a connector, a support member, a growth fluid supplier, a supply powder and a solvent, wherein the growth fluid supplier is provided with a storage space and an opening communicating with the storage space, and the connector comprises a first end and a second end; and the first end of the connector is connected to the base material, and the second end of the connector is detachably connected to the support member;
pouring the supply powder and the solvent into the storage space, and stirring and mixing the supply powder and the solvent, so as to obtain a growth fluid;
erecting the support member on the opening, and soaking the base material into the growth fluid; and
the base material absorbing the growth fluid, so as to form a crystalline ornament on a surface on the base material.

9. The method for growing the crystalline ornament according to claim 8, wherein the step that the first end of the connector is connected to the base material and the second end of the collector is connected to the support member is as follows: a support hole is formed in the support member, the connector comprises a connecting rod and a tail cap, the connecting rod comprises the first end and the second end, the base material is fixedly connected to the first end of the connecting rod, and when the second end of the connecting rod penetrates into a second side of the support member from a first side of the support member through the support hole, the tail cap is detachably covered on the second end of the connecting rod, so that the second end of the connecting rod is stopped at the second side.

10. The method for growing the crystalline ornament according to claim 8, wherein the step after the base material absorbs the growth fluid, so as to form a crystalline ornament on a surface on the base material is as follows:
disconnecting the second end of the connector with the support member;
providing a base; and
detachably inserting the second end of the connector to the base, so as to obtain a growable crystal.

11. The method for growing the crystalline ornament according to claim 8, wherein the step of base material absorbing the growth fluid, so as to form a crystalline ornament on a surface on the base material is as follows:
forming a plurality of water absorbing holes communicating with each other in the surface of the base material, the water absorbing holes absorbing the growth fluid so as to form an irregular crystalline ornament on the surface of the base material.

12. The method for growing the crystalline ornament according to claim 10, wherein the base is provided with a fixing matrix, which is fixedly connected inside the base, and the second end of the connector is detachably inserted into the fixing matrix.

13. A crystalline ornament, comprising:
a base material, wherein a crystalline ornament is provided on an outer surface of the base material;
a base, and
a connector, wherein the connector comprises a first end and a second end, the first end of the connector is connected to the base material, and the second end of the connector is connected to the base.

14. The crystalline ornament according to claim 13, wherein the first end of the connector is connected to the base material, and the second end of the connector is detachably connected to the base.

15. The crystalline ornament according to claim 14, wherein a base is provided with a fixing matrix, which is fixed connected inside the base, and the second end of the connector is detachably inserted into the fixing matrix.

16. The crystalline ornament according to claim 15, wherein a placing hole is formed in the fixing matrix, and the second end of the connector is detachably inserted into the placing hole.

17. The crystalline ornament according to claim 16, wherein an outer contour of the fixing matrix fits with an inner contour of a base, so that the fixing matrix is tightly fixed in a storage space of the base, and the placing hole is formed in a central position of the fixing matrix; and a top end of the fixing matrix is lower than that of the base and has a predetermined distance from the top end of the base.

18. The crystalline ornament according to claim 13, wherein the base material is made of a water absorbing material, the base is a plastic material, and a fixing matrix comprises a foam material.

19. The crystalline ornament according to claim 13, wherein the base material is spherical, a plurality of water absorbing holes are distributed in an outer surface of the base material, and the water absorbing holes are conducted mutually.

20. The crystalline ornament according to claim 13, wherein the crystalline ornament is an irregular crystalline ornament.
